(19) United States
(12) Patent Application Publication
(10) Pub. No.: US 2013/0317767 A1
(43) Pub. Date: Nov. 28, 2013

(54) MEASUREMENT ERROR CORRECTION METHOD AND ELECTRONIC COMPONENT CHARACTERISTIC MEASUREMENT APPARATUS

(71) Applicant: MURATA MANUFACTURING CO., LTD., Kyoto (JP)

(72) Inventor: Taichi MORI, Kyoto (JP)

(73) Assignee: MURATA MANUFACTURING CO., LTD., Kyoto (JP)

(21) Appl. No.: 13/956,053

(22) Filed: Jul. 31, 2013

Related U.S. Application Data
(63) Continuation of application No. PCT/JP2011/078624, filed on Dec. 10, 2011.

(30) Foreign Application Priority Data
Jan. 31, 2011 (JP) 2011-017814

(51) Int. Cl. G01R 35/00

(52) U.S. Cl. CPC G01R 35/005
USPC 702/57; 702/85

(57) ABSTRACT

In a measurement error correction method and an electronic component characteristic measurement apparatus, for each of correction-data acquisition samples having electrical characteristics different from one another, electrical characteristics S_{D}, S_{T} are measured in a first state in which the correction-data acquisition sample is mounted on a standard fixture and in a second state in which the correction-data acquisition sample is mounted on a test fixture, respectively. For each signal source port of a measurement system including a measuring instrument for measuring electrical characteristics, a mathematical expression that assumes the existence of a leakage signal that is transmitted directly between at least two ports of at least one of the standard fixture and the test fixture is determined. Electrical characteristics of a given electronic component are measured in the second state. By using the determined mathematical expressions, electrical characteristics if measurement were performed in the first state are calculated.

### CROSS REFERENCE TO RELATED APPLICATIONS

The present application is a continuation of International Application No. PCT/JP2011/078624 filed on Dec. 10, 2011, and claims priority to Japanese Patent Application No. 2011-017814 filed on Jan. 31, 2011, the entire contents of each of these applications being incorporated herein by reference in their entirety.

### TECHNICAL FIELD

The technical field relates to measurement error correction methods and electronic component characteristic measurement apparatuses. More particularly, the technical field relates to a measurement error correction method and an electronic component characteristic measurement apparatus for calculating, from a result obtained by measuring electrical characteristics of an electronic component with the electronic component mounted on a test fixture, an estimated value of electrical characteristics that would be obtained if measurement were performed with the electronic component mounted on a standard fixture.

### BACKGROUND

Conventionally, there have been proposed various methods for mathematically estimating a measured value that would be obtained using a standard fixture (a state assured to users or the like), from a measurement result obtained using a test fixture (for a mass production process).

For example, in a first method disclosed in GAKU KAMITANI (Murata manufacturing Co., Ltd.), “A METHOD TO CORRECT DIFFERENCE OF IN-FIXTURE MEASUREMENTS AMONG FIXTURES ON RF DEVICES”, APMC, 2003, Vol. 2, pp. 1094-1097 (Non Patent Documents 1) and J. P. DUNSMORE, L. BETTS (Agilent Technologies), “NEW METHODS FOR CORRELATING FIXTURED MEASUREMENTS”, APMC, 2003, Vol. 1, pp. 568-571 (Non Patent Document 2) and Japanese Patent No. 3558086 (Patent Document 1), a scattering matrix (referred to as a “relative correction adapter” in Non Patent Document 1 and Patent Document 1), which is a composition of a scattering matrix for removing errors of a test fixture and a scattering matrix of errors of a standard fixture, is derived for each port. The relative correction adaptor is then combined with a scattering matrix of values measured using the test fixture, whereby values that would be measured using the standard fixture are estimated. Each relative correction adapter can be calculated from measurement results obtained by measuring at least three one-port standard samples using the standard fixture and the test fixture for a corresponding port.

A second method (analytical relative correction method) disclosed in Japanese Patent No. 3558074 (Patent Document 2) uses the fact that the same sample is measured using a standard fixture and using a test fixture. True values of the sample are removed from a relational expression of values measured using the standard fixture and the true values of the sample and from a relational expression of values measured using the test fixture and the true values of the sample, so as to derive a relational expression of the values measured using the standard fixture and the values measured using the test fixture. This relational expression is then used to estimate values that would be measured using the standard fixture, from values measured using the test fixture. Unknown values in the relational expression are derived from values obtained by measuring standard samples using the standard fixture and the test fixture. The number of standard samples depends on the number of unknown values in the relational expression.

A third method disclosed in Agilent Technologies Application Note 1287-3 (Non Patent Document 3) is a method for deriving true values of a sample from measured values obtained by measuring the sample by a vector network analyzer (hereinafter, referred to as a “VNA”). That is, the third method is a VNA calibration method. In this method, a standard device whose true values are rated on the basis of its mechanical dimensions is measured by a measuring instrument that has not been calibrated. From a relationship between the obtained measured values and the true values of the standard device, errors of the measuring instrument are derived. A calculation for eliminating the errors from measured values of a sample is performed so as to estimate true values of the sample.

A fourth method disclosed in Japanese Unexamined Patent Application Publication No. 2004-309132 (Patent Document 3) is a method for calibrating a VNA, assuming that a fixture on which a sample having specific characteristics is mounted is a transfer standard device. In this method, calibration of the VNA is performed at an end of a cable to which the fixture is connected. Thereafter, the fixture is connected, and some samples having different characteristics are measured. In this way, true values for values obtained by measuring a certain sample using the fixture become available, and thus the fixture on which the sample having specific characteristics is mounted can be used as a transfer standard device. As a result, characteristics of the standard device can be changed by replacing the fixture that is rated as a transfer standard device and by replacing the sample. Thus, calibration can be performed at the end of the cable without requiring connection and disconnection between connectors during calibration.

A fifth method disclosed in Japanese Patent No. 3965701 (Patent Document 4) is a method in which an error model of the SOLT calibration is reflected in a relative correction adapter by extending the model of the above-described first method disclosed in Non Patent Documents 1 and 2 and Patent Document 1. Specifically, a standard sample for transmitting a signal between ports is prepared in addition to three one-port samples having different characteristics for each port. Depending on the position of a signal source, relative correction adapters of a port of the signal source and of a port to which a signal is transmitted are changed, thereby enabling correction of directivity or the like. For this reason, calibration of a measuring instrument is no longer required.

A sixth method disclosed in International Publication No. 2009/098816 (Patent Document 5) is a relative correction method (leakage error relative correction method) that takes into consideration a leakage signal caused in a fixture.

### SUMMARY

The present disclosure provides a measurement error correction method and an electronic component characteristic measurement apparatus that are capable of obtaining advantageous effects of a relative correction method, which is extendable to a given number of ports and in which a leakage signal between ports is modeled, without requiring calibration of a VNA.

In one aspect of the present disclosure, a measurement error correction method for calculating, for n (where n is a positive integer of 2 or greater) given ports, the n given ports being two or more ports of an electronic component, an estimated value of electrical characteristics that would be obtained if measurement were performed with the electronic component mounted on a standard fixture, from a result obtained by measuring electrical characteristics of the electronic component with the electronic component mounted on a test fixture, includes first to fifth steps. In the first step, for each of at least three first correction-data acquisition samples, electrical characteristics of the first correction-data acquisition sample are measured with the first correction-data acquisition sample mounted on the standard fixture, the first correction-data acquisition samples having electrical characteristics that are different from one another. In the second step, for each of samples, electrical characteristics of the sample are measured with the sample mounted on the test fixture, the samples being the at least three first correction-data acquisition samples, at least three second correction-data acquisition samples that can be considered to have electrical characteristics equivalent to those of the at least three first correction-data acquisition samples, or at least one third correction-data acquisition sample that can be considered to have electrical characteristics equivalent to those of at least one of the at least three first correction-data acquisition samples and the rest of the first correction-data acquisition samples. In the third step, for each of signal source ports of a measurement system including a measuring instrument for measuring electrical characteristics, a mathematical expression is determined from measurement results obtained in the first and second steps, the mathematical expression assuming the existence of leakage signals between at least two ports of at least one of the standard fixture and the test fixture, the leakage signals being signals that are not transmitted to the electronic component connected to the two ports but are directly transmitted between the two ports, the mathematical expression associating a measured value of electrical characteristics of an electronic component mounted on the test fixture with a measured value of electrical characteristics of the same electronic component mounted on the standard fixture. In the fourth step, electrical characteristics of a given electronic component are measured with the given electronic component mounted on the test fixture. In the fifth step, from a measurement result obtained in the fourth step, by using the mathematical expressions determined in the third step, electrical characteristics that would be obtained if measurement were performed on the electronic component with the electronic component mounted on the standard fixture are calculated.

In a more specific embodiment, each of the mathematical expressions determined in the third step may be a mathematical expression that assumes the existence of at least one leakage signal among the leakage signals between at least two ports of at least one of the standard fixture and the test fixture, the leakage signals being signals that are not transmitted to the electronic component connected to the two ports but are directly transmitted between the two ports.

In another more specific embodiment, the number of first correction-data acquisition samples may be 2n+2.

In another aspect, the present disclosure provides an electronic component characteristic measurement apparatus configured in the following manner.

An electronic component characteristic measurement apparatus calculates, for n (where n is a positive integer of 2 or greater) given ports, the n given ports being two or more ports of an electronic component, electrical characteristics that would be obtained if measurement were performed with the electronic component mounted on a standard fixture, from a result obtained by measuring electrical characteristics of the electronic component with the electronic component mounted on a test fixture. The electronic component characteristic measurement apparatus includes: (a) mathematical expression storage means for storing each mathematical expression determined for a corresponding one of signal source ports of a measurement system including a measuring instrument for measuring electrical characteristics, the mathematical expression assuming the existence of leakage signals between at least two ports of at least one of the standard fixture and the test fixture, the leakage signals being signals that are not transmitted to the electronic component connected to the two ports but are directly transmitted between the two ports, the mathematical expression associating a measured value of electrical characteristics of an electronic component mounted on the test fixture with a measured value of electrical characteristics of the same electronic component mounted on the standard fixture, the mathematical expression being determined from a first measurement result and a second measurement result, the first measurement result being obtained by measuring, for each of at least three first correction-data acquisition samples, electrical characteristics of the first correction-data acquisition sample with the first correction-data acquisition sample mounted on the standard fixture, the first correction-data acquisition samples having electrical characteristics that are different from one another, the second measurement result being obtained by measuring, for each of samples, electrical characteristics of the sample with the sample mounted on the test fixture, the samples being the at least three first correction-data acquisition samples, at least three second correction-data acquisition samples that can be considered to have electrical characteristics equivalent to those of the at least three first correction-data acquisition samples, or at least one third correction-data acquisition sample that can be considered to have electrical characteristics equivalent to those of at least one of the at least three first correction-data acquisition samples and the rest of the first correction-data acquisition samples; and (b) electrical characteristic estimating means for calculating, from a result obtained by measuring electrical characteristics of a given electronic component with the given electronic component mounted on the test fixture, by using the mathematical expressions stored in the mathematical expression storage means, electrical characteristics that would be obtained if measurement were performed on the electronic component with the electronic component mounted on the standard fixture.

### BRIEF DESCRIPTION OF DRAWINGS

FIG. 1 is a schematic diagram of an explanatory example of a measurement system in the case of measuring electrical characteristics by using a VNA.

FIG. 2 is a signal flow diagram illustrating a two-port measurement error model according to an exemplary embodiment.

FIG. 3 is a signal flow diagram illustrating a two-port measurement error model according to an exemplary embodiment.

FIG. 4 is a signal flow diagram illustrating a conventional example of a two-port measurement error model.

FIG. 5 is a signal flow diagram illustrating a two-port measurement error model according to an exemplary embodiment.

FIG. 6 is a signal flow diagram illustrating a two-port measurement error model according to an exemplary embodiment.

FIG. 7 is a block diagram illustrating a measurement error model according to an exemplary embodiment.

FIG. 8 is a signal flow diagram illustrating errors when measurement is performed using a standard fixture according to an exemplary embodiment.

FIG. 9 is a signal flow diagram illustrating errors when measurement is performed using a test fixture according to an exemplary embodiment.

FIG. 10 is a signal flow diagram illustrating errors when measurement is performed using the test fixture according to an exemplary embodiment.

FIG. 11 is an explanatory diagram of a measurement system according to an exemplary embodiment.

FIG. 12 is a signal flow diagram illustrating an explanatory example of a basic principle of a relative correction method.

FIG. 13 is a signal flow diagram illustrating the basic principle of the relative correction method.

### DETAILED DESCRIPTION

The inventor realized the following problems associated with the above-described methods:

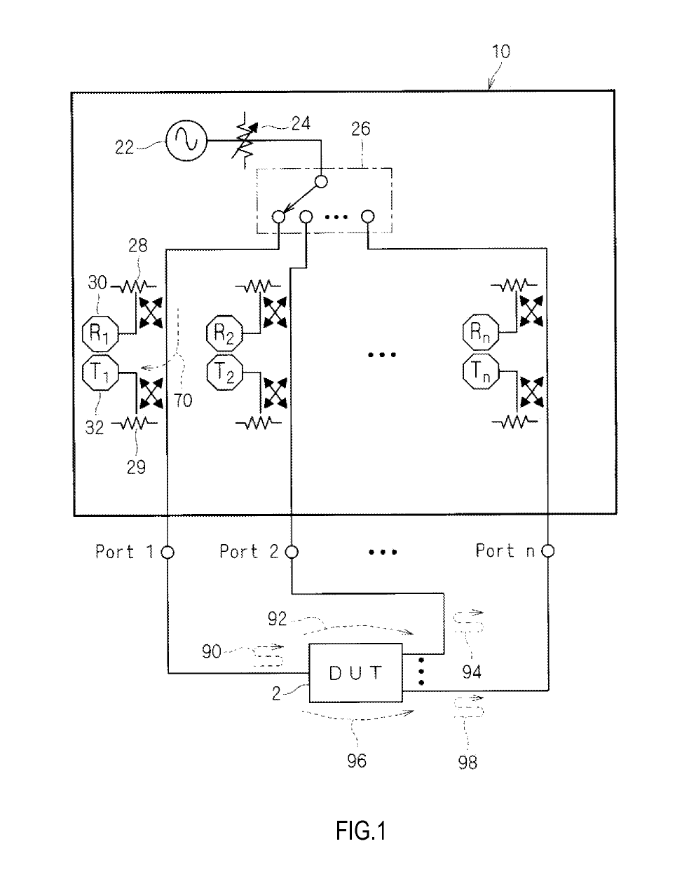

FIG. 1 is a schematic diagram illustrating error factors in the case of measuring electrical characteristics of a sample (device under test (DUT)) 2 by using a vector network analyzer (VNA) 10.

As illustrated in FIG. 1, in the VNA 10, a signal source 22 is connected to a switch 26 via a variable attenuator 24. Each of ports switched between by the switch 26 is connected to a corresponding reference receiver 30 via a corresponding directivity coupler 28 and to a corresponding test receiver 32 via a corresponding directivity coupler 29. Each of the ports of the VNA 10 is electrically connected to a corresponding one of ports of the DUT 2.

In the case where a port 1 serves as a signal source, directivity errors denoted by a broken-line arrow 70 are caused inside the VNA 10. Also, source match errors denoted by a chain-line arrow 90, isolation errors denoted by chain-line arrows 92 and 96, and load match errors denoted by chain-line arrows 94 and 98 are caused outside the VNA 20.

In the VNA 10, signal-source ports are switched between by the switch 26. Accordingly, errors caused inside the VNA 10 change every time one port is switched to another one by the switch 26. For this reason, characteristics of the DUT 2 cannot be accurately measured unless values of errors caused inside the VNA 10 are defined for each of the signal-source ports.

In the first method disclosed in Non Patent Documents 1 and 2 and Patent Document 1, an error model is created in order to correct a difference between errors of fixtures. Thus, error factors of a VNA are not coped with. In order to obtain sufficient correction accuracy, the VNA needs to be calibrated when measurements are performed using a standard fixture and a test fixture in the case of using the correction-adapter-type relative correction method. Accordingly, in a production process, a calibration work is frequently performed with a connector of a fixture disconnected from a cable. This, however, increases the number of man-hours because manual calibration is troublesome. In addition, the connector is repeatedly connected or disconnected manually. This consequently causes a break in the semi-rigid cable, wearing out of the connector, wearing out of a calibration standard device, a variation of fastening strength of the connector, and the like.

In the second method disclosed in Patent Document 2, error factors of a VNA are modeled in an error model of the analytical relative correction method. Thus, calibration of the VNA need not be performed when the analytical relative correction method is used. However, in the method disclosed in Patent Document 2 for deriving a relational expression used for determining values that would be measured using a standard fixture from values measured using a test fixture, specifically, a method for deriving a relational expression between the values measured using the test fixture and values measured using the standard fixture by eliminating true values of a standard sample from relational expressions of the measured values and the true values of the standard sample for the measured values on the assumption that the true values of standard sample are identical during measurement using the standard fixture and measurement using the test fixture, the relational expression is determined only for up to two ports due to mathematical difficulties. Thus, samples having three or more ports cannot be not handled by the second method. Also, leakage errors defined in this method are simplified and all leakage errors are not modeled. For this reason, there is an issue that errors occur due to simplification.

In the third method disclosed in Non Patent Document 3, a calibration plane can be created just in front of a sample because a standard device is precisely created for a coaxial (waveguide) sample. However, it is practically impossible to precisely create a standard device for a non-coaxial (non-waveguide) sample, and thus it is difficult to create a calibration plane just in front of a sample. Accordingly, measurement of a non-coaxial (non-waveguide) sample using a measurement fixture involves an issue that measurement reproducibility is not achieved due to a variation in error factors between measurement fixtures because calibration cannot be performed at the end of the fixtures.

In the fourth method disclosed in Patent Document 3, a set of a fixture and a sample functions as a transfer standard device, and thus a VNA can be calibrated without disconnecting the connector from the VNA. However, this method involves an issue that measurement reproducibility is not achieved due to a variation in error factors between measurement fixtures because the calibration plane is at an end of a cable to which the fixture is connected.

In the fifth method disclosed in Patent Document 4, in the case where a leakage signal between ports of a measurement system becomes problematic, errors are caused because the leakage signal is not modeled.

An exemplary embodiment that can address the above shortcomings will now be described with reference to the drawings.

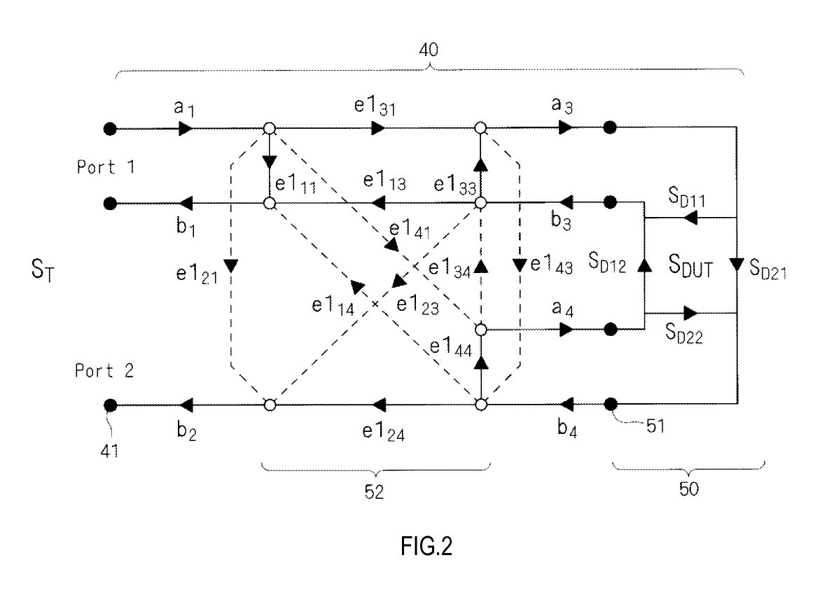

Referring to FIGS. 2 to 13, the exemplary embodiment of the present disclosure will be described below.

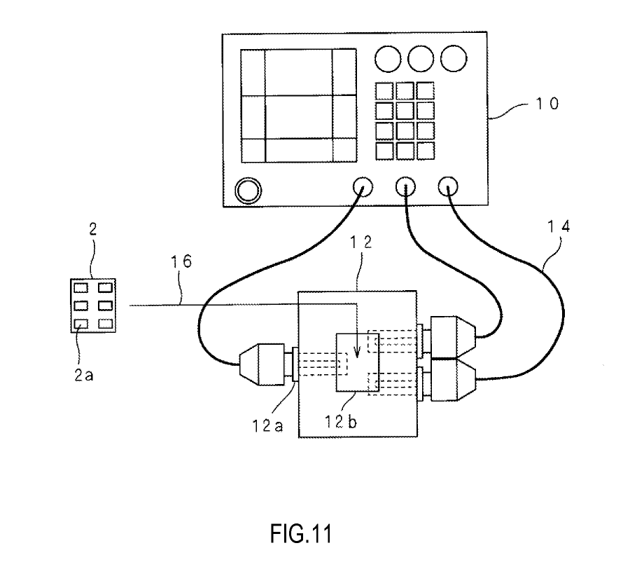

Measurement System: As illustrated in FIG. 11, an electronic component 2 (for example, a surface-acoustic-wave filter which is a high-frequency passive electronic component) is mounted on a fixture 12. In this state, electrical characteristics of the electronic component 2 are measured by a measurement apparatus 10 (for example, a VNA). Each coaxial connector 12a of the fixture 12 and the measurement apparatus 10 are connected to each other by a corresponding coaxial cable 14. As indicated by an arrow 16, when the electronic component 2 is mounted on a mount portion 12b of the fixture 12, terminals 2a of the electronic component 2 are electrically connected to the measurement apparatus 10. The measurement apparatus 10 inputs a signal to a given terminal among the terminals 2a of the electronic component 2 and detects an output signal output from another terminal, so as to measure electrical characteristics of the electronic component 2.

In accordance with a certain program, the measurement apparatus 10 performs computation processing on measurement data so as to calculate electrical characteristics of the electronic component 2. The measurement apparatus 10 reads out necessary data, such as measured values and parameters used in computation, from an internal memory or recording medium. Alternatively, the measurement apparatus 10 communicates with an external device (for example, a server), reads out necessary data, temporarily stores the data in a memory, and reads out the data from the memory if necessary. In this case, the measurement apparatus 10 includes a mathematical expression storage means, an electrical characteristic estimating means, and a measuring means for performing measurement on an electronic component.

The measurement apparatus 10 may be divided into a plurality of devices. For example, the measurement apparatus 10 may be divided into a measuring unit (the measuring means) for performing measurement, and a computation unit (the mathematical expression storage means and the electrical characteristic estimating means) for receiving measurement data and performing electrical characteristics computation processing and quality checking.

It is difficult to create a plurality of fixtures 12 having identical characteristics. For this reason, if different fixtures 12 are used in measurement, measurement results for the same electronic component 2 differ from one another because the characteristics of the fixtures 12 vary one another. For example, a measurement result obtained with a fixture (standard fixture) used for assuring electrical characteristics to users differs from that obtained with a fixture (test fixture) used in measurement for selecting high-quality electronic components in a production process of electronic components. Such a difference in the measured values between fixtures can be corrected using a relative correction method.

A procedure of correcting measurement errors by using the relative correction method is as follows:

(Step 1) For each of a certain number of correction-data acquisition samples, electrical characteristics of the sample are measured with the sample mounted on a standard fixture.
(Step 2) For each of the certain number of correction-data acquisition samples whose electrical characteristics are measured with the sample mounted on the standard fixture, electrical characteristics of the sample are measured with the sample mounted on a test fixture.
(Step 3) From data measured with the samples mounted on the standard fixture in step 1 and data measured with the samples mounted on the test fixture in step 2, a mathematical expression for associating measured values of electrical characteristics measured with an electronic component mounted on the test fixture and measured values of electrical characteristics measured with the same electronic component mounted on the standard fixture is determined.
(Step 4) Electrical characteristics of a given electronic component are measured with the electronic component mounted on the test fixture.
(Step 5) The mathematical expression determined in step 3 is used to calculate, for the electronic component whose electrical characteristics are measured in step 4, electrical characteristics that would be obtained if measurement were performed with the electronic component mounted on the standard fixture.

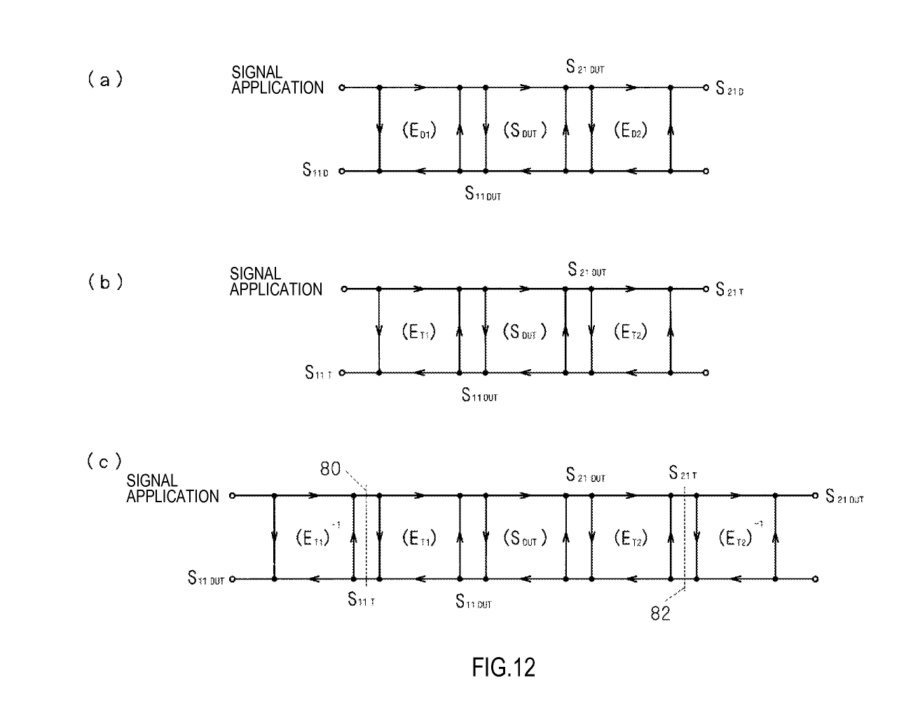

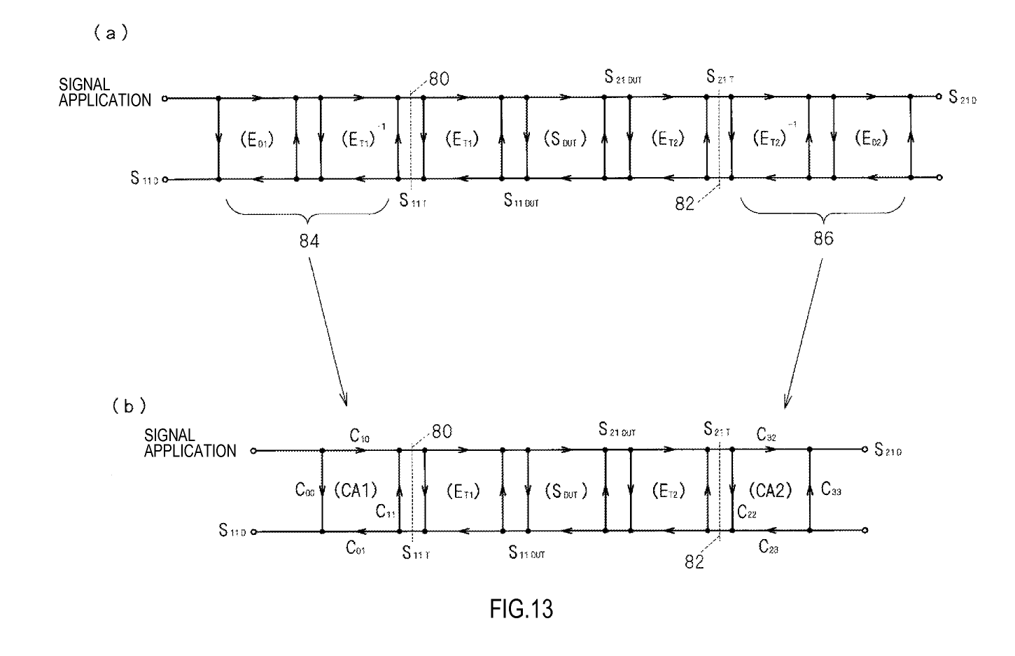

Relative Correction Method: Referring next to FIGS. 12 and 13, a basic principle of the relative correction method will be described. For simplicity, electrical characteristics between two ports are described below by way of example; however, the number of ports is extendable to n ports (n is an integer of 1, or 3 or greater).

Part (a) of FIG. 12 is a signal flow diagram for a standard fixture on which a two-port electronic component (hereinafter, referred to as a “sample DUT”) is mounted. A scattering matrix (S_{DUT}) denotes characteristics of the sample DUT. Scattering matrices (E_{D1}) and (E_{D2}) each denote error characteristics between corresponding coaxial connectors of the standard fixture and corresponding ports of the sample DUT. At terminals on the respective sides of the signal flow diagram, measured values obtained with the sample DUT mounted on the standard fixture (hereinafter, also referred to as “standard fixture measured values”) S_{11D} and S_{21D} are obtained.

Part (b) of FIG. 12 is a signal flow diagram for a test fixture on which the sample DUT is mounted. The scattering matrix (S_{DUT}) denotes characteristics of the sample DUT. Scattering matrices (E_{T1}) and (E_{T2}) each denote error characteristics between corresponding coaxial connectors of the test fixture and corresponding ports of the sample DUT. At terminals on the respective sides of the signal flow diagram, measured values obtained with the sample DUT mounted on the test fixture (hereinafter, also referred to as “test fixture measured values”) S_{11T} and S_{21T} are obtained.

Part (c) of FIG. 12 illustrates a state in which adapters (E_{T1})⁻¹ and (E_{T2})⁻¹ that respectively cancel the error characteristics (E_{T1}) and (E_{T2}) are connected to the respective sides of the signal flow diagram of part (b) of FIG. 12. These adapters (E_{T1})⁻¹ and (E_{T2})⁻¹ are theoretically obtained by transforming the scattering matrices (E_{T1}) and (E_{T2}) of the error characteristics into transfer matrices, determining inverse matrices of the transfer matrices, and again transforming the inverse matrices into scattering matrices, respectively. At a boundary 80 between the error characteristics (E_{T1}) and the adapter (E_{T1}) and a boundary 82 between the error characteristics (E_{T2}) and the adapter (E_{T2})-1, the test fixture measurement values S_{11T} and S_{21T} which are measured with the sample DUT mounted on the test fixture are obtained, respectively. Errors of the test fixture are removed, and consequently measured values S_{11DUT} and S_{21DUT} of the sample DUT itself are obtained at terminals on the respective sides of the signal flow diagram of part (c) of FIG. 12.

The signal flow diagram of part (c) of FIG. 12 is equivalent to a signal flow diagram of the sample DUT. When the scattering matrices (E_{D1}) and (E_{D2}) of the error characteristics of the standard fixture are connected to the respective sides as in part (a) of FIG. 12, part (a) of FIG. 13 is obtained.

Let (CA1) denote a scattering matrix obtained by combining (E_{D1}) and (E_{T1})⁻¹, which are denoted by a reference numeral 84 in part (a) of FIG. 13. Let (CA2) denote a scattering matrix obtained by combining (E_{T2})⁻¹ and (E_{D2}), which are denoted by a reference numeral 86. Then, part (b) of FIG. 13 is obtained. These scattering matrices (CA1) and (CA2) are so-called “relative correction adapters”. The scattering matrix (CA1) associates the test fixture measured value S_{11T} with the standard fixture measured value S_{11D}, whereas the scattering matrix (CA2) associates the test fixture measured value S_{21T} with the standard fixture measured value S_{21D}. Thus, once the relative correction adapters (CA1) and (CA2) are determined, it is possible to calculate (estimate) the standard fixture measured values S_{11D} and S_{21D} by using the relative correction adapters (CA1) and (CA2), from the test fixture measured values S_{11T} and S_{21T} which are obtained with a given electronic component mounted on the test fixture, respectively.

The relative correction adapters (CA1) and (CA2) each include four coefficients: c₀₀, c₀₁, c₁₀, and c₁₁; and c₂₂, c₂₃, c₃₂, and c₃₃. Here, c₀₁=c₁₀ and c₂₃=c₃₂ in accordance with the reciprocal theorem. Thus, the coefficients c₀₀, c₀₁, c₁₀, c₁₁, c₂₂, c₂₃, c₃₂, and c₃₃ can be determined using measured values that are measured with each of three one-port standard samples (correction-data acquisition samples) having different characteristics mounted on the standard fixture and the test fixture between ports.

Basic characteristics of correction-data acquisition samples used for calculating the relative correction adapters need to be as follows: a transfer factor between ports is sufficiently small, and reflection coefficient characteristics at the same port and frequency differ between the correction-data acquisition samples. Since it is a matter of the reflection coefficient, forming an open circuit, a short circuit, and a termination is a simple way to achieve the above-described basic characteristics of the correction-data acquisition samples. Also, the correction-data acquisition samples preferably have an outer shape that can be mounted on fixtures just like samples subjected to correction.

An open circuit, a short circuit, and a termination between ports can be implemented by connecting a signal line in the same package as a measurement-target sample to ground via a lead, chip resistor, or the like inside the package. With this method, however, it is difficult to arrange a component, such as a chip resistor, inside the package when the measurement-target sample is downsized, and thus correction-data acquisition samples cannot be created. As a result, this may make it impossible to perform selection of high-quality products using the relative correction method.

To cope with this, correction-data acquisition samples are created using a production process of measurement-target samples (electronic components). In this case, the correction-data acquisition samples may be created using a production line for producing electronic components serving as products, a production line for experimentally producing the prototype of electronic components, or both production lines.

Also, since it is theoretically sufficient that a correction-data acquisition sample mounted on a standard fixture and a correction-data acquisition sample mounted on a test fixture have the same electrical characteristics, they need not be the same one. For example, a plurality of correction-data acquisition samples that can be considered to have the same electrical characteristics are prepared. Correction-data acquisition samples randomly selected from the prepared correction-data acquisition samples are respectively mounted on the standard fixture and the test fixture and are subjected to measurement. In this way, relative correction adapters can also be derived.

Error Model: Next, an error model of the relative correction method will be described.

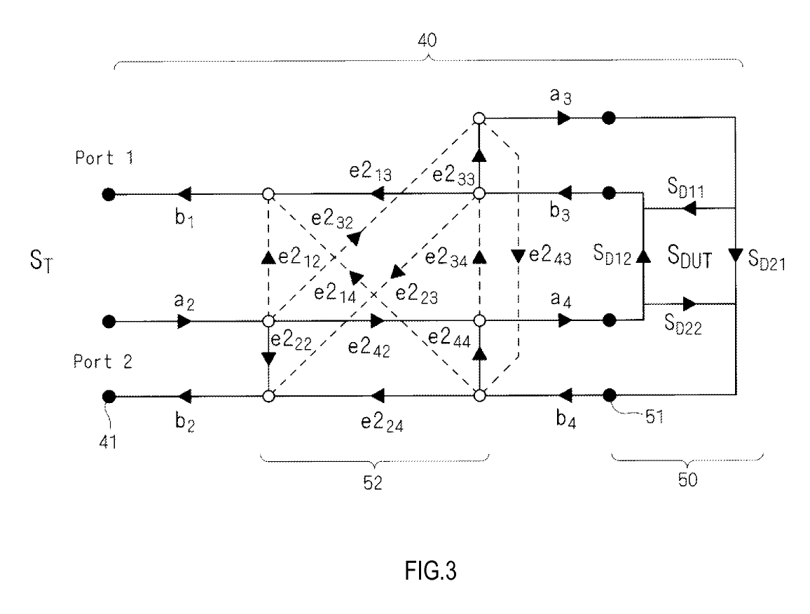

FIGS. 2 and 3 are signal flow diagrams of error models used in the present disclosure. FIG. 2 illustrates the case where Port 1 serves as a signal source port. FIG. 3 illustrates the case where Port 2 serves as a signal source port.

Arrows illustrated with a broken line in FIGS. 2 and 3 represent leakage signals. An error model used in the present disclosure includes leakage errors between ports and errors caused inside the VNA (errors of the VNA). In a portion 40 which is equivalent to a state in which a subject sample is mounted on a standard measurement fixture, a portion 52 which is equivalent to a relative correction adapter is connected to a portion 50 which is equivalent to a state in which the subject sample is mounted on a test measurement fixture.

Meanings of symbols used in FIGS. 2 and 3 are as follows:

S_{D}: A value of a subject sample (hereinafter, referred to as DUT)
S_{T}: A measured value of DUT affected by error parameters
e1ᵢⱼ: A VNA error parameter in the case where Port 1 serves as a signal source
e2ᵢⱼ: A VNA error parameter in the case where Port 2 serves as a signal source
aᵢ: An input signal to a corresponding measurement system
bᵢ: An output signal from a corresponding measurement system

When it is assumed that S_{D} of FIGS. 2 and 3 denotes a standard fixture measured value and S_{T} denotes a test fixture measured value measured by a VNA that has not been calibrated, this model can also be considered as a model of a leakage error relative correction method, disclosed in Patent Document 5, that includes VNA error parameters of the test fixture measurement system. In this case, e1ᵢⱼ and e2ᵢⱼ are results obtained by determining inverse matrices of T-parameters of relative correction adapters and transforming the inverse matrices into S-parameters.

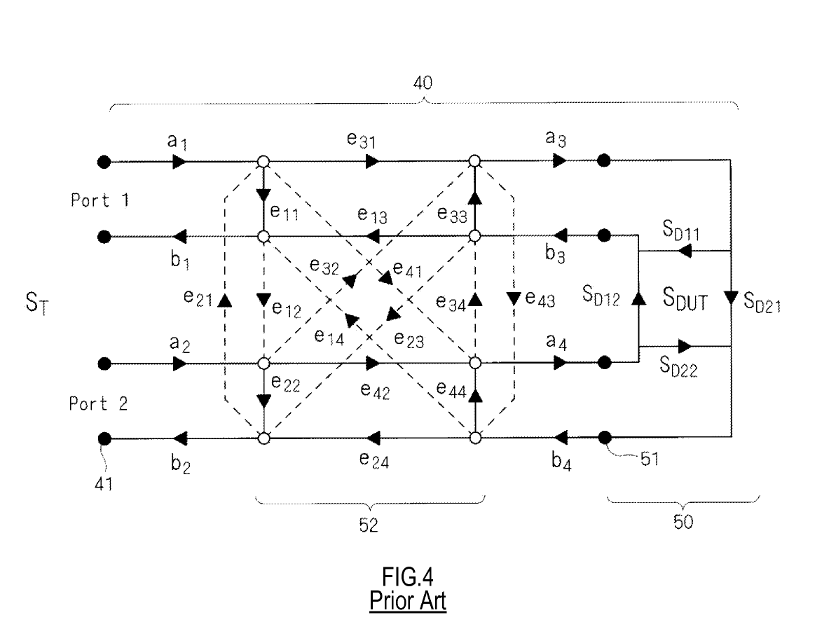

FIG. 4 illustrates a signal flow diagram of an error model of the leakage error relative correction method (hereinafter, referred to as a conventional method) disclosed in Patent Document 5. As in FIGS. 2 and 3, eᵢⱼ of FIG. 4 is also a result obtained by determining an inverse matrix of T-parameters of a relative correction adapter and transforming the inverse matrix into S-parameters.

The error model of the leakage error relative correction method (hereinafter, referred to as a conventional method) disclosed in Patent Document 5 includes leakage errors between ports but does not include errors of the VNA. Thus, the same correction coefficient is used for different signal source ports. The error model of the present disclosure includes errors of the VNA, and thus the correction coefficient needs to be defined for each of the different signal source ports.

Comparison of the number of parameters of the relative correction adapter of the present disclosure including the VNA error parameters (the number of parameters is equal to the sum of e1ᵢⱼ and e2ᵢⱼ of FIGS. 2 and 3) with the number of parameters of the relative correction adapter of the conventional method (the number of parameters is equal to the sum of e1ᵢⱼ of FIG. 4) reveals that there are 24 parameters for the present disclosure and 16 for the conventional method. That is, the number of parameters of the relative correction adapter is increased in the present disclosure by the number of added VNA error parameters.

The table below illustrates a comparison result of the number of relative correction parameters between the present disclosure and the conventional method with respect to the number of measurement ports.

TABLE

| | |
|---|---|
| | Number of parameters of relative |
| Number of | correction adapter |

| ports | Present disclosure | Conventional method |
|---|---|---|
| 2 | 24 | 16 |
| 3 | 189 | 81 |
| 4 | 832 | 256 |

When zero is assigned to the parameters for the leakage signals between ports, the model of the present disclosure can be considered as a correction model including VNA error parameters of the test fixture measurement system in the case where leakage signals between ports are not taken into consideration.

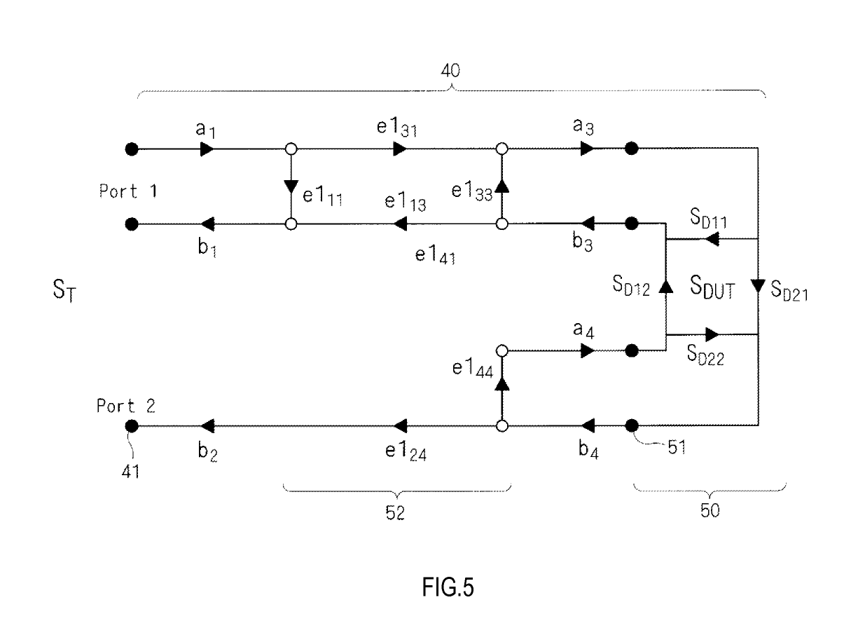

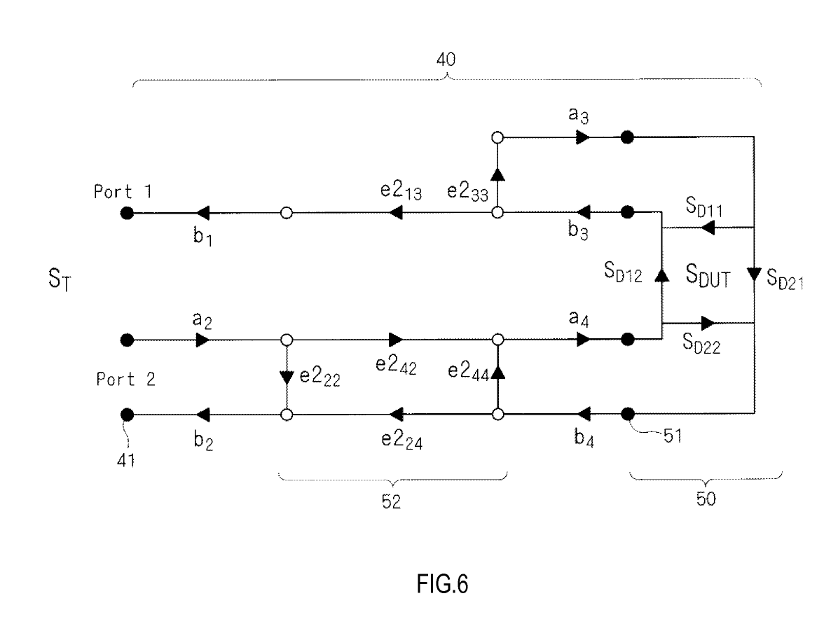

FIGS. 5 and 6 illustrate signal flow diagrams of error models for the case where isolation between ports is ensured in the standard fixture and the test fixture. FIG. 5 illustrates the case where Port 1 serves as a signal source port. FIG. 6 illustrates the case where Port 2 serves as a signal source port.

FIGS. 5 and 6 illustrate the case where all leakage signals between ports illustrated with a broken line in FIGS. 2 and 3 are zero. However, to make some of the leakage signals between ports zero, zero is assigned to parameters relating to the leakage signals between ports that are made zero.

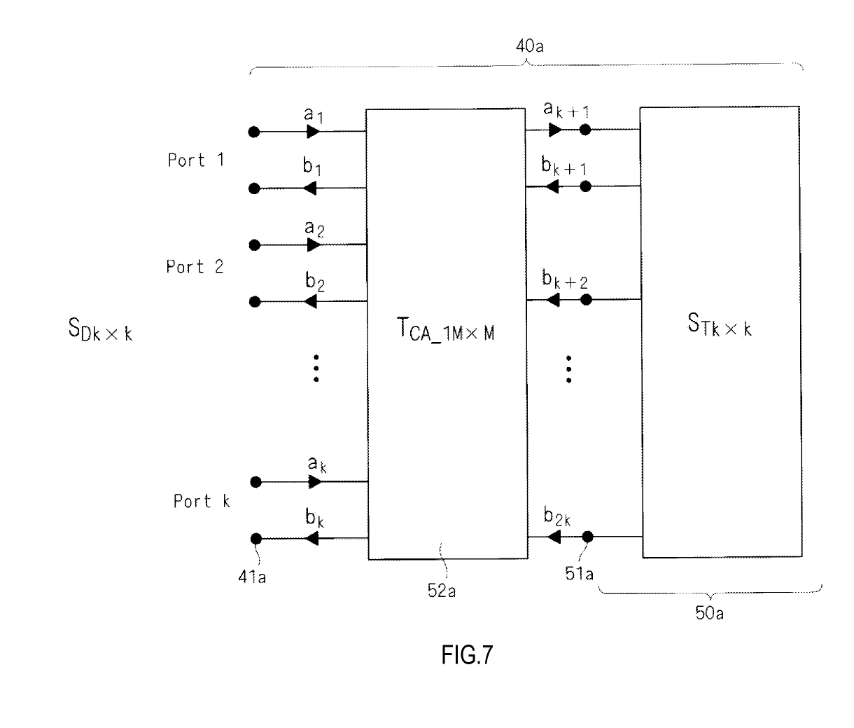

FIG. 7 illustrates a relative correction model of the present disclosure for the case where Port 1 serves as a signal source port of the test fixture measurement system in a k-port measurement system.

Meanings of symbols used in FIG. 7 are as follows:

S_{D}: S-parameters of a standard fixture measured value
S_{T}: S-parameters of a test fixture measured value
T_{CA}_{_{—}}₁: T-parameters of the relative correction adapter of the present disclosure for the case where Port 1 serves as a signal source port of the test fixture measurement system
aᵢ: An input signal to a corresponding measurement system
bᵢ: An output signal from a corresponding measurement system
k: The number of ports of the measurement system

### M: 2×k

The S-parameters (S_{T}) of a portion 50a which is equivalent to a state in which a subject sample is mounted on a test measurement fixture is denoted by a k×k matrix. The T-parameters (T_{CA}_{_{—}}₁) of a portion 52a which is equivalent to the relative correction adapter is denoted by an M×M matrix. The S-parameters (S_{D}) of a portion 40a which is equivalent to a state in which the subject sample is mounted on the standard measurement fixture is denoted by a k×k matrix.

A relationship illustrated in FIG. 7 is expressed in matrix representation. Then, Expression 1 below is obtained.

$$\begin{matrix}[ Math . 1 ] & \\ ( \begin{matrix}{b}_{1} \\ {b}_{2} \\ ⋮ \\ {b}_{k} \\ {a}_{1} \\ {a}_{2} \\ ⋮ \\ {a}_{k}\end{matrix} ) = {T}_{CA \_ 1} \cdot ( \begin{matrix}{b}_{k + 1} \\ {b}_{k + 2} \\ ⋮ \\ {b}_{2 k} \\ {a}_{k + 1} \\ 0 \\ ⋮ \\ 0\end{matrix} ) & Expression 1\end{matrix}$$

There is no input signal from ports other than Port 1 which is a signal source port of the test fixture measurement system. Thus, in Expression 1, input signals to the test fixture measurement system other than aₖ₊₁ are zero.

Accordingly, the matrix representation is not affected even if values of columns, from the (k+1)-th column and other than the (k+1)-th column, of T_{CA}_{_{—}}₁ of Expression 1 are set to be a given value x. That is, parameters of T_{CA}_{_{—}}₁ that are set to be the given value x need not be derived.

Expression 2 below denotes a relationship among input and output signals of the measurement system and the T-parameters of the relative correction adapter of the present disclosure for the case where a port j serves as a signal source port of the test fixture measurement system.

$$\begin{matrix}[ Math . 2 ] & \\ ( \begin{matrix}{b}_{1} \\ {b}_{2} \\ ⋮ \\ {b}_{k} \\ {a}_{1} \\ ⋮ \\ {a}_{j} \\ ⋮ \\ {a}_{k}\end{matrix} ) = {T}_{CA \_ j} \cdot ( \begin{matrix}{b}_{k + 1} \\ {b}_{k + 2} \\ ⋮ \\ {b}_{2 k} \\ 0 \\ ⋮ \\ {a}_{k + j} \\ ⋮ \\ 0\end{matrix} ) & Expression 2\end{matrix}$$

In the case of Expression 2, the matrix representation is not affected even if values of columns, from the (k+1)-th column and other than the (k+j)-th column, of T_{CA}_{_{—}}ⱼ are set to be the given value x. Therefore, parameters of T_{CA}_{_{—}}ⱼ that are set to be the given value x need not be derived similarly to T_{CA}_{_{—}}₁.

For each of all ports used in measurement of characteristics of an electronic component, T_{CA}_{_{—}}ⱼ is derived for the case where the port serves as a signal source. The resulting T_{CA}_{_{—}}ⱼ for all the ports serve as relative correction adapters of the present disclosure.

Method for Deriving Relative Correction Adapter: Next, a method for deriving a relative correction adapter of the present disclosure will be described.

The relative correction adapter T_{CA}_{_{—}}ⱼ for the case where the port j serves as a signal source port of the test fixture measurement system can be derived by using computational expressions of the relative correction adapter according to the conventional method. Expressions 3 to 8 show the computational expressions of the conventional method.

[Math. 3]

C₍ₖ_{²}_{*N}_{_{std}}_{)×(4*k}_{²}₋₁₎·t_{CA}_{_{—}}_{(4*k}_{²}_{-1)×1}′=ν₍ₖ_{²}_{*N}_{_{std}}_{)×1} Expression 3

Meanings of symbols used in Expression 3 are as follows:

t_{CA}_{_{—}}_{(4*k}_{²}_{-1)×1}′: A matrix obtained by performing column expansion on T_{CA} and performing normalization using one given
T_{CA} parameter (See Expressions 5 and 6)
C₍ₖ_{²}_{*Nstd)×(4*k}_{²}₋₁₎: See Expressions 4 to 7
ν₍ₖ_{²}_{*Nstd)×1}: See Expression 8 [Math. 4]

[(Sᵢ_{_{—}}_{T}^{t}Iₖ)\textcircled{×}(−IₖSᵢ_{_{—}}_{D})]·t_{CA}_{_{—}}ⱼ_{_{—}}_{4*k}_{²}_{×1}=Aᵢ_{_{—}}ₖ_{²}_{×4*k}_{²}·t_{CA}_{_{—}}ⱼ_{_{—}}_{4*k}_{²}_{×1}=0 Expression 4

### Here,

### [Math. 4a]

\textcircled{×}

denotes the Kronecker product.

Meanings of symbols used in Expression 4 are as follows:

Sᵢ_{_{—}}_{T}: A test fixture measured value of an i-th standard sample
Sᵢ_{_{—}}_{D}: A standard fixture measured value of the i-th standard sample
t_{CA}: A matrix obtained by performing column expansion on T_{CA} (see Expression 5)
lₖ: A k×k unit matrix

$${t}_{CA 4 * {k}^{2} \times 1} = cs [ {T}_{CA \_ 2 * k \times 2 * k} ] = ( \begin{matrix}{t}_{{CA}_{11}} \\ {t}_{{CA}_{21}} \\ ⋮ \\ {t}_{{CA}_{2 * k 2 * k}}\end{matrix} ) \qquad [ Math . 5 ]$$

### Here,

$$cs [ ] \qquad [ Math . 5 a ]$$

denotes column expansion.

$$\begin{matrix} [ Math . 6 ] & \\ \frac{1}{- {t}_{CA 11}} \cdot {A}_{i \_ {k}^{2} \times 4 * {k}^{2}} \cdot {t}_{CA \_ 4 * {k}^{2} \times 1} = {A}_{i \_ {k}^{2} \times 4 * {k}^{2}} \cdot ( \begin{matrix}- 1 \\ {t}_{CA \_ ( 4 * {k}^{2} - 1 ) \times {1}^{′}}\end{matrix} ) = ( {u}_{i \_ {k}^{2} \times 1} {B}_{i \_ {k}^{2} \times ( 4 * {k}^{2} - 1 )} ) \cdot ( \begin{matrix}- 1 \\ {t}_{CA \_ ( 4 * {k}^{2} - 1 ) \times {1}^{′}}\end{matrix} ) = - {u}_{i \_ {k}^{2} \times 1} + {B}_{i \_ {k}^{2} ( 4 * {k}^{2} - 1 )} \cdot {t}_{CA \_ ( 4 * {k}^{2} - 1 ) \times {1}^{′}} & Expression 6 \\ [ Math . 7 ] & \\ {C}_{( {k}^{2} * {N}_{std} ) \times ( 4 * {k}^{2} - 1 )} = ( \begin{matrix}{B}_{1 \_ {k}^{2} \times ( 4 * {k}^{2} - 1 )} \\ ⋮ \\ {B}_{{N}_{std } \_ {k}^{2} ( 4 * {k}^{2} - 1 )}\end{matrix} ) & Expression 7 \\ [ Math . 8 ] & \\ {v}_{( {k}^{2} * {N}_{std} ) \times 1} = ( \begin{matrix}{u}_{1 \_ {k}^{2} \times 1} \\ ⋮ \\ {u}_{{N}_{std -} {k}^{2} \times 1}\end{matrix} ) & Expression 8\end{matrix}$$

In the present disclosure, following processing is uniquely performed on C₍ₖ_{²}_{*Nstd)×(4*k}_{²}₋₁₎ of Expression 3. Here, assume that C₍ₖ_{²}_{*Nstd)×(4*k}_{²}₋₁₎ when the port j serves as a signal source is denoted by Cⱼ_{_{—}}₍ₖ_{²}_{*Nstd)×(4*k}_{²}₋₁₎.

(1) All columns of Cⱼ_{_{—}}₍ₖ_{²}_{*Nstd)×(4*k}_{²}₋₁₎ that are multiplied by elements set to be the given value in t_{CA}_{_{—}}ⱼ′ are deleted. This reduces the number of columns, and Cⱼ_{_{—}}₍ₖ_{²}_{*Nstd)×(2*k}_{²}_{+2*k-1)} is obtained.
(2) Values of Sᵢ_{_{—}}_{T} other than measured values that are measured when the port j serves as a signal source are set to be zero. That is, columns other than the j-th column of the S-parameter matrix of Sᵢ_{_{—}}_{T} are set to be zero.
(3) As a result of performing the processing (1) and (2), columns whose values are all zero appear in Cⱼ_{_{—}}₍ₖ_{²}_{*Nstd)×(2*k}_{²}_{+2*k-1)} Although calculation can be performed in this state, it is desirable to delete such columns in terms of reducing the amount of calculation. As a result, Cⱼ_{_{—}}_{(k*Nstd)×(2*k}_{²}_{+2*k-1)} is obtained.

As a result of this processing, Expression 3 is converted into Expression 9.

[Math. 9]

Cⱼ_{_{—}}_{(k*N}_{_{std}}_{)×(2*k}_{²}_{+2*k-1)}·t_{CA}_{_{—}}_{j(2*k}_{²}_{+2*k-1)×1}′=ν_{(k*N}_{_{std}}_{)×1} Expression 9

Expression 9 is solved for each case where a corresponding port serves as a signal source port. All resulting t_{CA}_{_{—j}}_{_{—}}_{j(2*k}_{²}_{+2*k-1)×1}′ are the relative correction adapters of the present disclosure, and are used to perform a relative correction computation of the present disclosure. A calculation method for solving Expression 9 is the least-squares method as in the conventional method.

The number of standard samples necessary for solving Expression 9 is (2*k²+2*k−1)/k or more. Here, (2*k²+2*k−1)/k is equal to 2k+2−1/k and k is a positive integer. Thus, the number of standard samples (correction-data acquisition samples) necessary for solving Expression 9 is denoted by Expression 10.

[Math. 10]

The number of standard samples≧2k+2 Expression 10

In accordance with Expression 10, the minimum number of standard samples necessary for solving Expression 9 is, for example, six in a two-port measurement system, eight in a three-port measurement system, and ten in a four-port measurement system.

Correction Computational Expression: Next, a correction computational expression using the relative correction adapters of the present disclosure will be described.

As indicated by Expression 11, T_{CA}_{_{—}}ⱼ′ is divided into four. Each divided matrix is a k×k matrix, where k denotes the number of ports.

$$\begin{matrix}[ Math . 11 ] & \\ {T}_{CA \_ {j}^{′}} = ( \begin{matrix}{T}_{CA 11 \_ {j}^{′}} & {T}_{CA 12 \_ {j}^{′}} \\ {T}_{CA 21 \_ {j}^{′}} & {T}_{CA 22 \_ {j}^{′}}\end{matrix} ) & Expression 11\end{matrix}$$

Also, a relationship between S_{D} and signals are denoted by Expression 12.

$$\begin{matrix}[ Math . 12 ] & \\ ( \begin{matrix}{b}_{1} \\ {b}_{2} \\ ⋮ \\ {b}_{k}\end{matrix} ) = {S}_{D} \cdot ( \begin{matrix}{a}_{1} \\ {a}_{2} \\ ⋮ \\ {a}_{k}\end{matrix} ) & Expression 12\end{matrix}$$

Expression 2 is denoted by Expressions 13 and 14 by using Expression 11.

$$\begin{matrix}[ Math . 13 ] & \\ ( \begin{matrix}{b}_{1} \\ {b}_{2} \\ ⋮ \\ {b}_{k}\end{matrix} ) = {T}_{CA 11 \_ {j}^{′}} \cdot ( \begin{matrix}{b}_{k + 1} \\ {b}_{k + 2} \\ ⋮ \\ {b}_{2 k}\end{matrix} ) + {T}_{CA 12 \_ {j}^{′}} \cdot ( \begin{matrix}0 \\ ⋮ \\ 0 \\ {a}_{k + j} \\ 0 \\ ⋮ \\ 0\end{matrix} ) & Expression 13 \\ [ Math . 14 ] & \\ ( \begin{matrix}{a}_{1} \\ {a}_{2} \\ ⋮ \\ {a}_{k}\end{matrix} ) = {T}_{CA 21 \_ {j}^{′}} \cdot ( \begin{matrix}{b}_{k + 1} \\ {b}_{k + 2} \\ ⋮ \\ {b}_{2 k}\end{matrix} ) + {T}_{CA 22 \_ {j}^{′}} \cdot ( \begin{matrix}0 \\ ⋮ \\ 0 \\ {a}_{k + j} \\ 0 \\ ⋮ \\ 0\end{matrix} ) & Expression 14\end{matrix}$$

Expressions 13 and 14 are substituted into Expression 12, and both sides are divided by aₖ₊ⱼ. Then, Expression 15 is obtained. Expression 15 is a basic formula of the correction formula of the present disclosure. As is apparent from the description above, positions of the value of S_{T} to be substituted and 0 or 1 values in Expression 15 differ depending on the port number of a port that serves as a signal source.

$$\begin{matrix} [ Math . 15 ] & \\ {T}_{CA 11 \_ {j}^{′}} \cdot ( \begin{matrix}{S}_{Tj 1} \\ ⋮ \\ {ST}_{Tjj} \\ ⋮ \\ {S}_{Tjk}\end{matrix} ) + {T}_{CA 12 \_ {j}^{′}} \cdot ( \begin{matrix}0 \\ ⋮ \\ 1 \\ ⋮ \\ 0\end{matrix} ) = {S}_{D} \cdot [ {T}_{CA 21 \_ {j}^{′}} \cdot ( \begin{matrix}{S}_{Tj 1} \\ ⋮ \\ {S}_{Tjj} \\ ⋮ \\ {S}_{Tjk}\end{matrix} ) + {T}_{CA 22 \_ {j}^{′}} \cdot ( \begin{matrix}0 \\ ⋮ \\ 1 \\ ⋮ \\ 0\end{matrix} ) ] & Expression 15\end{matrix}$$

Expression 15 is denoted by Expression 16 in an easy-to-understand manner. Each of V and W denotes a k×1 matrix.

[Math. 16]

Vⱼ=S_{D}·Wⱼ Expression 16

The calculation denoted by Expression 15 is performed for each of Port 1 to Port k for the case where the port serves as a signal source, so as to derive V and W. After deriving V and W, all the resulting of V and W are combined, whereby Expression 17 is obtained.

[Math. 17]

(V₁ . . . Vⱼ . . . Vₖ)=S_{D}·(W₁ . . . Wⱼ . . . Wₖ) Expression 17

From Expression 17, S_{D} can be denoted by Expression 18.

[Math. 18]

S_{D}=(V₁ . . . Vⱼ . . . Vₖ)·(W₁ . . . Wⱼ . . . Wₖ)⁻¹ Expression 19

In this way, the correction calculation of the present disclosure for a given number of ports, i.e., k ports, can be performed.

As described above, relative adapters are determined using an error model that assumes the existence of leakage signals in a measurement system including a VNA, and correction calculation is performed using the relative adapters. In this way, measured values can be corrected including errors of the VNA. For this reason, even if calibration of the VNA is not performed, it is possible to perform relative correction between a measurement system which includes a measuring instrument and a standard fixture and a measurement system which includes the measuring instrument and a test fixture by modeling all leakage error coefficients between ports.

Example for Two Ports: In the case of two ports, Expressions 3 to 8 and 11 to 18 are denoted as follows. The expression number with the prime corresponds to the corresponding expression number for the case of a given number

$$\begin{matrix} [ Math . 19 ] & \\ {C}_{4 * {N}_{std} \times 15} \cdot {t}_{CA \_ 15 \times {1}^{′}} = {v}_{4 * {N}_{std} \times 1} & Expression {19}^{′} \\ [ Math . 20 ] & \\ ⌊ ( {S}_{i \_ T}^{t} {I}_{2} ) ⊗ ( - {I}_{2} {S}_{i \_ D} ) ⌋ \cdot {t}_{CA \_ j \_ 16 \times 1} \cdot {t}_{CA \_ j \_ 16 \times 1} = 0 & Expression {20}^{′} \\ [ Math . 21 ] & \\ {t}_{CA \_ 16 \times 1} = cs [ {T}_{CA \_ 4 \times 4} ] = ( \begin{matrix}{t}_{{CA}_{11}} \\ {t}_{CA 21} \\ ⋮ \\ {t}_{{CA }_{44}}\end{matrix} ) & Expression {21}^{′} \\ [ Math . 22 ] & \\ \frac{1}{- {t}_{CA 11}} \cdot {A}_{i \_ 4 \times 16} \cdot {t}_{CA \_ 16 \times 1} = {A}_{i \_ 4 \times 16} \cdot ( \begin{matrix}- 1 \\ {t}_{CA \_ 15 \times {1}^{′}}\end{matrix} ) = ( \begin{matrix}{u}_{i \_ 4 \times 1} & {B}_{i \_ 4 \times 15}\end{matrix} ) ( \begin{matrix}- 1 \\ {t}_{CA \_ 15 \times {1}^{′}}\end{matrix} ) = - {u}_{t \_ 4 \times 1} + {B}_{i \_ 4 \times 15} \cdot {t}_{CA \_ 15 \times {1}^{′}} = 0 & Expression {22}^{′} \\ [ Math . 23 ] & \\ {C}_{4 * {N}_{std} \times 15} = ( \begin{matrix}{B}_{1 \_ 4 \times 15} \\ ⋮ \\ {B}_{{N}_{std} - 4 \times 15}\end{matrix} ) & Expression {23}^{′} \\ [ Math . 24 ] & \\ {v}_{4 * {N}_{std} \times 1} = ( \begin{matrix}{u}_{1 \_ 4 \times 1} \\ ⋮ \\ {u}_{{N}_{std} \_ 4 \times 1}\end{matrix} ) & Expression {24}^{′} \\ [ Math . 25 ] & \\ {T}_{CA \_ {j}^{′}} = ( \begin{matrix}{T}_{CA 11 \_ {j}^{′}} & {T}_{CA 12 \_ {j}^{′}} \\ {T}_{CA 21 \_ {j}^{′}} & {T}_{CA 22 \_ {j}^{′}}\end{matrix} ) & Expression {25}^{′} \\ [ Math . 26 ] & \\ ( \begin{matrix}{b}_{1} \\ {b}_{2}\end{matrix} ) = {S}_{D} \cdot ( \begin{matrix}{a}_{1} \\ {a}_{2}\end{matrix} ) & Expression {26}^{′} \\ [ Math . 27 ] & \\ ( \begin{matrix}{b}_{1} \\ {b}_{2}\end{matrix} ) = {T}_{CA 11 \_ {t}^{′}} \cdot ( \begin{matrix}{b}_{3} \\ {b}_{4 }\end{matrix} ) + {T}_{CA 12 \_ {j}^{′ }} \cdot ( \begin{matrix}{a}_{3} \\ 0\end{matrix} ) & Expression {27}^{′} \\ [ Math . 28 ] & \\ ( \begin{matrix}{a}_{1} \\ {a}_{2}\end{matrix} ) = {T}_{CA 21 \_ {j}^{′}} \cdot ( \begin{matrix}{b}_{3} \\ {b}_{4}\end{matrix} ) + {T}_{CA 22 \_ {j}^{′}} \cdot ( \begin{matrix}{a}_{3} \\ 0\end{matrix} ) & Expression {28}^{′} \\ [ Math . 29 ] & \\ {T}_{CA 11 \_ {1}^{′}} \cdot ( \begin{matrix}{S}_{T 11} \\ {S}_{T 21}\end{matrix} ) + {T}_{CA 12 \_ {1}^{′}} \cdot ( \begin{matrix}1 \\ 0\end{matrix} ) = {S}_{D} \cdot [ {T}_{CA 21 \_ {1}^{′}} \cdot ( \begin{matrix}{S}_{T 11} \\ {S}_{T 21}\end{matrix} ) + {T}_{CA 22 \_ {1}^{′ }} \cdot ( \begin{matrix}1 \\ 0\end{matrix} ) ] & Expression {29}^{′} \\ [ Math . 30 ] & \\ {V}_{1} = {S}_{D} \cdot {W}_{1} & Expression {30}^{′} \\ [ Math . 31 ] & \\ ( {V}_{1} {V}_{2} ) = {S}_{D} \cdot ( {W}_{1} {W}_{2} ) & Expression {31}^{′} \\ [ Math . 32 ] & \\ {S}_{D} = ( {V}_{1} {V}_{2} ) \cdot {( {W}_{1} {W}_{2} )}^{- 1} & Expression {32}^{′}\end{matrix}$$

Simulation: Next, simulation for the case of two ports by using Expressions 19′ to 32′ will be described.

A procedure of the simulation is as follows:

(1) Errors of a standard fixture and errors of a test fixture are determined.
(2) Relative correction adapters T_{CA}_{_{—}}ⱼ are calculated from (1)
(3) Values of six standard samples are determined.
(4) Measured values of the six standard samples obtained with the standard fixture and with the test fixture are calculated.
(5) Relative correction adapters of the present disclosure are derived.
(6) It is checked whether results of (5) match results of (2).

The following describes details about simulation conditions.

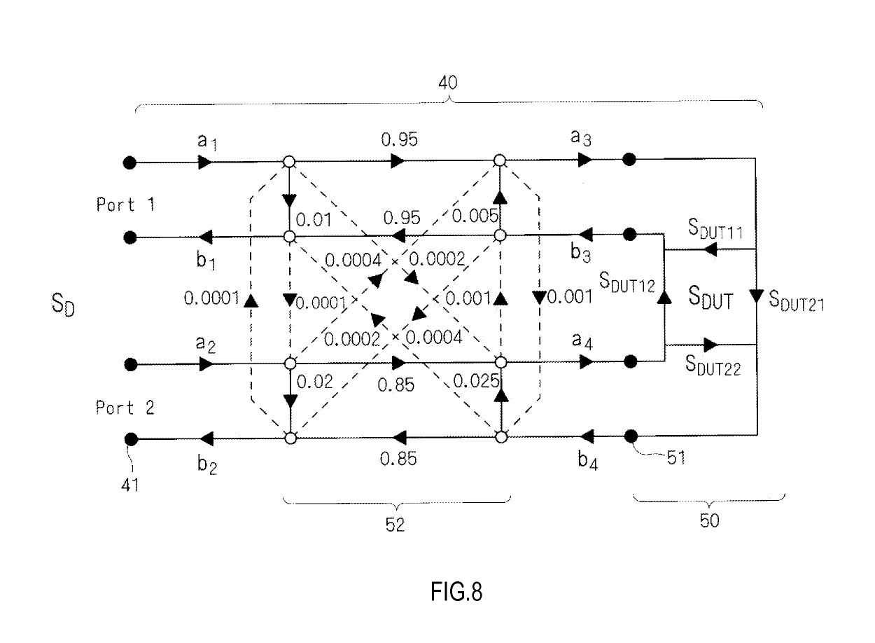

FIGS. 8, 9, 10 illustrate errors of a standard fixture and a test fixture used in simulation by using signal flow graphs.

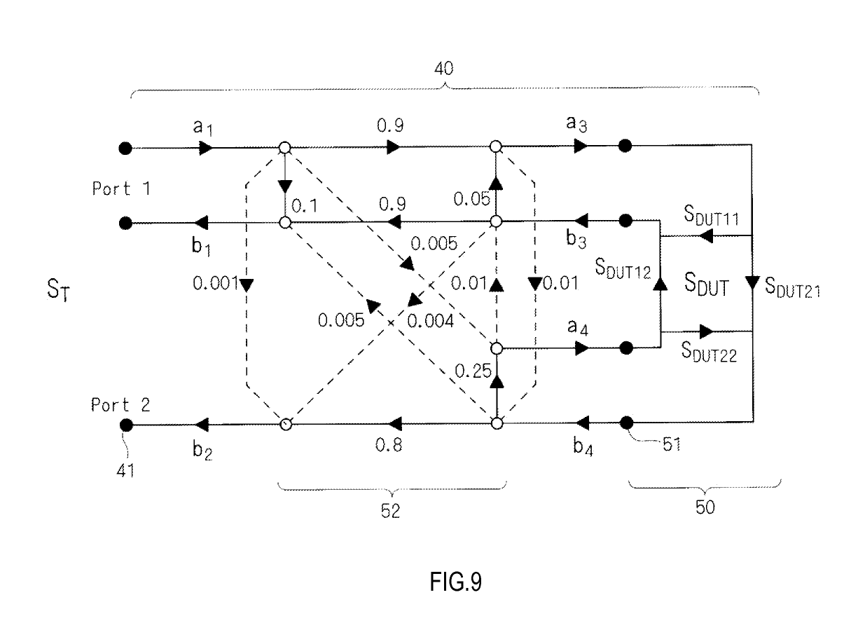

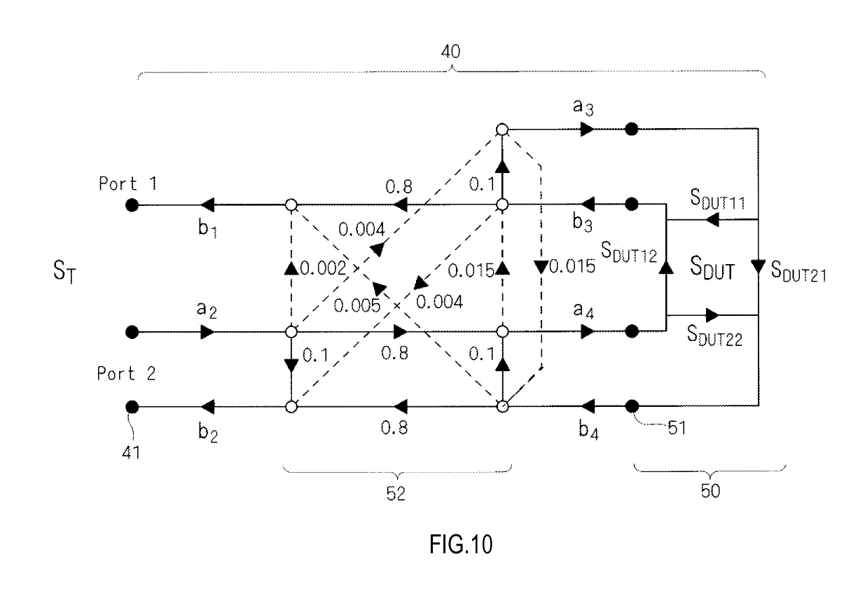

In accordance with measured values of the test fixture illustrated in FIGS. 9 and 10, true values T_{CA} of relative correction adapters used for correction into measured values of the standard fixture illustrated in FIG. 8 are shown below.

$$\begin{matrix} [ Math . 33 ] & \\ {T}_{CA \_ {1}^{′}} = ( \begin{matrix}- 1 & 0.005871 & 0.091023 & x \\ 0.003851 & - 1.01234 & 0.000430 & x \\ - 0.049783 & - 0.010770 & - 0.892044 & x \\ - 0.009736 & - 0.313239 & - 0.004072 & x\end{matrix} ) \\ {T}_{CA \_ {2}^{′}} = ( \begin{matrix}- 1 & 0.010779 & x & 0.000819 \\ 0.001213 & - 0.796127 & x & 0.061797 \\ - 0.105111 & - 0.012571 & x & 0.000071 \\ - 0.017088 & - 0.082277 & x & - 0.882416\end{matrix} ) & Expression 33\end{matrix}$$

Set true values of the six standard samples are shown below. The description method “STD# (characteristics of Port 1/characteristics of Port 2)=S-parameters” is used.

$$\begin{matrix}[ Math . 34 ] & \\ STD 1 ( Open / Open ) = ( \begin{matrix}0.9 & 0.001 \\ 0.001 & 0.95\end{matrix} ) \\ STD 2 ( Short / Short ) = ( \begin{matrix}- 0.9 & - 0.001 \\ - 0.001 & - 0.85\end{matrix} ) \\ STD 3 ( Load / Load ) = ( \begin{matrix}0.1 & 0.003 \\ 0.003 & 0.9\end{matrix} ) \\ STD 4 ( Thru ) = ( \begin{matrix}0.05 & 0.9 \\ 0.9 & 0.04\end{matrix} ) \\ STD 5 ( - 20 dBAtt ) = ( \begin{matrix}0.1 & 0.1 \\ 0.1 & 0.05\end{matrix} ) \\ STD 6 ( SeriesR ) = ( \begin{matrix}0.45 & 0.5 \\ 0.5 & 0.4\end{matrix} ) & Expression 34\end{matrix}$$

The simulation results are as follows:

The calculation results of the relative correction adapters of the present disclosure are denoted by Expression 35.

$$\begin{matrix} [ Math . 35 ] & \\ {T}_{CA \_ 1} = ( \begin{matrix}- 1 & 0.005871 & 0.091023 & x \\ 0.003851 & - 1.01234 & 0.000430 & x \\ - 0.049783 & - 0.010770 & - 0.892044 & x \\ - 0.009736 & - 0.313239 & - 0.004072 & x\end{matrix} ) \\ {T}_{C A \_ 2} = ( \begin{matrix}- 1 & 0.010779 & x & 0.000819 \\ 0.001213 & - 0.796127 & x & 0.061797 \\ - 0.105111 & - 0.012571 & x & 0.000071 \\ - 0.017088 & - 0.082277 & x & - 0.882416\end{matrix} ) & Expression 35\end{matrix}$$

The calculation result of the present disclosure denoted by Expression 35 matches Expression 33 which indicates the result obtained from simulation. Accordingly, it can be proved that relative correction adapters including leakage errors for VNA errors which differ from one signal source port to another can be derived by the present disclosure.

Summary: As described above, applying a relative correction method using a measurement error correction model including errors of a measuring instrument makes it possible to perform relative correction between a measurement system which includes a measuring instrument and a standard fixture and a measurement system which includes the measuring instrument and a test fixture by modeling all leakage error coefficients between ports, even if calibration of the measuring instrument is not performed.

Note that the present disclosure is not limited to the above embodiment and can be carried out with various alterations.

For example, correction can be made by assigning zero to parameters of leakage signals between ports that are not to be modeled intentionally.

Measurement with an electronic component mounted on a standard fixture and measurement with the electronic component mounted on a test fixture may be conducted using the same measuring instrument or different measuring instruments. When different measuring instruments are used, from electrical characteristics measured by a first measuring instrument using the standard fixture and electrical characteristics measured by a second measuring instrument using the test fixture, a mathematical expression that associates electrical characteristics of an electronic component measured by the first measuring instrument using the standard fixture with electrical characteristics of the same electronic component measured by the second measuring instrument using the test fixture is determined. Then, using the determined mathematical expression, electrical characteristics that would be obtained if measurement were performed by the first measuring instrument using the standard fixture is estimated from electrical characteristics of a given electronic component measured by the second measuring instrument with the electronic component mounted on the test fixture.

In embodiments of a method according to the present disclosure, electrical characteristics can be corrected including errors of a measuring instrument by using a mathematical expression that assumes the existence of a leakage signal in a measurement system including the measuring instrument. Accordingly, even if calibration of the measuring instrument is not performed, it is possible to perform relative correction between a measurement system which includes the measuring instrument and a standard fixture and a measurement system which includes the measuring instrument and a test fixture by modeling all leakage error coefficients between ports.

In an embodiment in which each of the mathematical expressions determined in the third step is a mathematical expression that assumes the existence of at least one leakage signal among the leakage signals between at least two ports of at least one of the standard fixture and the test fixture, the leakage signals being signals that are not transmitted to the electronic component connected to the two ports but are directly transmitted between the two ports, the number of leakage error coefficients can be reduced, and thus the operation can be simplified. For example, it is possible to reduce a time required for the operation of the first and second steps by reducing the number of correction-data acquisition samples or to reduce a time required for determining the mathematical expression in the third step.

In an embodiment in which the number of first correction-data acquisition samples is 2n+2, the number of correction-data acquisition samples is minimized, and thus efficiency of the measurement operation can be improved.

With the above-described configuration of an electronic component characteristic measurement apparatus, even if calibration of a measuring instrument is not performed, it is possible to perform relative correction between a measurement system which includes the measuring instrument and a standard fixture and a measurement system which includes the measuring instrument and a test fixture by modeling all leakage error coefficients between ports.

Embodiments according to the present disclosure have advantageous effects of a relative correction method which is extendable to a given number of ports and in which a leakage signal between ports is modeled can be obtained without requiring calibration of a VNA.

1. A measurement error correction method, implemented by a processor, for calculating, for n (where n is a positive integer of 2 or greater) given ports, the n given ports being two or more ports of an electronic component, an estimated value of electrical characteristics that would be obtained if measurement were performed with the electronic component mounted on a standard fixture, from a result obtained by measuring electrical characteristics of the electronic component with the electronic component mounted on a test fixture, the measurement error correction method comprising:
a first step of measuring, for each of at least three first correction-data acquisition samples, electrical characteristics of the first correction-data acquisition sample with the first correction-data acquisition sample mounted on the standard fixture, the first correction-data acquisition samples having electrical characteristics that are different from one another;
a second step of measuring, for each of samples, electrical characteristics of the sample with the sample mounted on the test fixture, the samples being the at least three first correction-data acquisition samples, at least three second correction-data acquisition samples that can be considered to have electrical characteristics equivalent to those of the at least three first correction-data acquisition samples, or at least one third correction-data acquisition sample that can be considered to have electrical characteristics equivalent to those of at least one of the at least three first correction-data acquisition samples and the rest of the first correction-data acquisition samples;
a third step of determining, for each of signal source ports of a measurement system including a measuring instrument for measuring electrical characteristics, a mathematical expression from measurement results obtained in the first and second steps, the mathematical expression assuming the existence of leakage signals between at least two ports of at least one of the standard fixture and the test fixture, the leakage signals being signals that are not transmitted to the electronic component connected to the two ports but are directly transmitted between the two ports, the mathematical expression associating a measured value of electrical characteristics of an electronic component mounted on the test fixture with a measured value of electrical characteristics of the same electronic component mounted on the standard fixture;
a fourth step of measuring electrical characteristics of a given electronic component with the given electronic component mounted on the test fixture; and
a fifth step of calculating, from a measurement result obtained in the fourth step, by using the mathematical expressions determined in the third step, electrical characteristics that would be obtained if measurement were performed on the electronic component with the electronic component mounted on the standard fixture.

2. The measurement error correction method according to claim 1, wherein each of the mathematical expressions determined in the third step is a mathematical expression that assumes the existence of at least one leakage signal among the leakage signals between at least two ports of at least one of the standard fixture and the test fixture, the leakage signals being signals that are not transmitted to the electronic component connected to the two ports but are directly transmitted between the two ports.

3. The measurement error correction method according to claim 1, wherein the number of first correction-data acquisition samples is 2n+2.

4. The measurement error correction method according to claim 2, wherein the number of first correction-data acquisition samples is 2n+2.

5. An electronic component characteristic measurement apparatus that calculates, for n (where n is a positive integer of 2 or greater) given ports, the n given ports being two or more ports of an electronic component, electrical characteristics that would be obtained if measurement were performed with the electronic component mounted on a standard fixture, from a result obtained by measuring electrical characteristics of the electronic component with the electronic component mounted on a test fixture, the electronic component characteristic measurement apparatus comprising:
a processor;
mathematical expression storage communicatively coupled to the processor and configured to store each mathematical expression determined for a corresponding one of signal source ports of a measurement system including a measuring instrument for measuring electrical characteristics, the mathematical expression assuming the existence of leakage signals between at least two ports of at least one of the standard fixture and the test fixture, the leakage signals being signals that are not transmitted to the electronic component connected to the two ports but are directly transmitted between the two ports, the mathematical expression associating a measured value of electrical characteristics of an electronic component mounted on the test fixture with a measured value of electrical characteristics of the same electronic component mounted on the standard fixture, the mathematical expression being determined from a first measurement result and a second measurement result, the first measurement result being obtained by measuring, for each of at least three first correction-data acquisition samples, electrical characteristics of the first correction-data acquisition sample with the first correction-data acquisition sample mounted on the standard fixture, the first correction-data acquisition samples having electrical characteristics that are different from one another, the second measurement result being obtained by measuring, for each of samples, electrical characteristics of the sample with the sample mounted on the test fixture, the samples being the at least three first correction-data acquisition samples, at least three second correction-data acquisition samples that can be considered to have electrical characteristics equivalent to those of the at least three first correction-data acquisition samples, or at least one third correction-data acquisition sample that can be considered to have electrical characteristics equivalent to those of at least one of the at least three first correction-data acquisition samples and the rest of the first correction-data acquisition samples; and
electrical characteristic estimator configured to calculate, using the processor, from a result obtained by measuring electrical characteristics of a given electronic component with the given electronic component mounted on the test fixture, by using the mathematical expressions stored in the mathematical expression storage means, electrical characteristics that would be obtained if measurement were performed on the electronic component with the electronic component mounted on the standard fixture.
